(19) United States
(12) Patent Application Publication
(10) Pub. No.: US 2005/0161745 A1
(43) Pub. Date: Jul. 28, 2005

(54) CMOS device, method for fabricating the same and method for generating mask data

(75) Inventors: Tokuhiko Tamaki, Osaka (JP); Hiromasa Fujimoto, Kyoto (JP); Takatoshi Yasui, Osaka (JP); Takehiro Hirai, Shiga (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/028,526

(22) Filed: Jan. 5, 2005

(30) Foreign Application Priority Data
Jan. 27, 2004 (JP) 2004-018302

(51) Int. Cl. H01L 21/8238; H01L 29/76; H01L 31/062

(52) U.S. Cl. 257/369; 438/199

(57) ABSTRACT

An NMIS gate implantation layer is generated by a method in which mask data of a P-type well implantation layer are added to mask data obtained by subtracting mask data of an NMIS-SD implantation layer and PMIS-SD implantation layer from mask data of an N-type well implantation layer. In a CMOS device fabricating process, ions are implanted into a polysilicon film by using the NMIS gate implantation layer, resulting in reduction in the total numbers of PN junctions and non-doped regions in a gate polysilicon film.

### CROSS-REFERENCE TO RELATED APPLICATIONS

The disclosure of Japanese Patent Application No. 2004-018302 filed on Jan. 27, 2004 including specification, drawing and claims is incorporated herein by reference in its entirety.

### BACKGROUND OF THE INVENTION

(1) Field of the Invention

The present invention relates to a semiconductor device adopting a silicided CMOS dual-gate structure, a method for fabricating the same and a method for generating mask data.

(2) Description of Related Art

In recent years, with decrease in voltages of CMOS devices, there has arisen a need to adjust threshold voltages of NMISFETs and PMISFETs to high accuracy. Therefore, CMOS devices with a dual-gate structure have been commonly used. Generally, CMOS devices with a dual-gate structure mean devices each using an N-type impurity-doped polysilicon film as a gate electrode of an NMISFET and a P-type impurity-doped polysilicon film as a gate electrode of a PMISFET (see, for example, Japanese Unexamined Patent Publication No. 6-275788 (Abstract)). For CMOS devices with a dual-gate structure, respective gate electrodes of an NMISFET and a PMISFET typically exist in a single gate polysilicon film. Hence, a PN junction is produced in the gate polysilicon film. In this case, so-called polycide gate electrodes obtained by siliciding the upper part of the gate polysilicon film are often used for such a CMOS device with a dual-gate structure to ensure reliable conductivity in the gate polysilicon film (see, for example, Japanese Unexamined Patent Publication No. 9-289257 (Abstract)).

In processes for fabricating a CMOS device with a dual-gate structure, methods for introducing an N-type impurity into an NMISFET region of a gate polysilicon film and a P-type impurity into a PMISFET region thereof include the following:
(1) a method in which a polysilicon film is doped by ion implantation with impurities before a gate polysilicon film is formed by the patterning of the flat-shaped polysilicon film; and
(2) a method in which a gate polysilicon film is doped with impurities simultaneously with implantation of impurity ions into a substrate for the formation of source/drain regions of MISFETs.

On the other hand, as gate insulating films become thinner with miniaturization in MISFETs, boron used as a P-type impurity for gate electrodes of PMISFETs diffuses more extensively into gate polysilicon films and the diffused boron adversely affects the reliability of the MISFETs. Therefore, in many cases, a gate electrode of a PMISFET in the gate polysilicon film is doped with impurities by the method (2), and the gate electrode of the NMISFET therein is doped with impurities by the method (1) or (2).

FIGS. 2A and 2B are a plan view showing the structure of a typical CMOS inverter circuit and a cross-sectional view taken along the line II-II of FIG. 2A, respectively. In FIGS. 2A and 2B, interconnect layers are not shown.

As shown in FIG. 2B, a CMOS device comprises a silicon substrate 1, a P-type well 2 and an N-type well 3 both provided in the silicon substrate 1, and a trench isolation region 4 formed in the top surface region of the silicon substrate 1. The P-type well 2 contains a P-type impurity at a low concentration, and the upper part of the P-type well 2 serves as an active region of an NMISFET. The N-type well 3 contains an N-type impurity at a low concentration, and the upper part of the N-type well 3 serves as an active region of a PMISFET. A gate insulating film 5 made of a silicon oxide film or a silicon oxynitride film is formed on regions of the silicon substrate 1 surrounded by the trench isolation region 4. A gate polysilicon film 6 is formed on the gate insulating film 5 to extend from the trench isolation region 4 across the active regions of the silicon substrate 1 and serves as gate electrodes on the active regions of the silicon substrate 1 and as gate interconnects on the other parts of the silicon substrate 1.

As shown in FIG. 2A, while an implantation mask having an opening 11 is used in a process step of implanting impurity ions into the P-type well 2, an implantation mask having an opening 12 is used in a process step of implanting impurity ions into the N-type well 3. Furthermore, as shown in FIG. 2A, the NMISFET comprises source/drain regions 21 containing an N-type impurity at a high concentration and a well contact region 22 containing a P-type impurity at a high concentration. The PMISFET comprises source/drain regions 23 containing a P-type impurity at a high concentration and a well contact region 24 containing an N-type impurity at a high concentration. While an implantation mask having openings 13 and 15 is used in a process step of implanting impurity ions into the source/drain regions 21 of the NMISFET, an implantation mask having openings 14 and 16 is used in a process step of implanting impurity ions into the source/drain regions 23 of the PMISFET. Contacts 26 are connected to the source/drain regions 21 and 23 to allow electrical connection with an upper interconnect (not shown).

The gate polysilicon film 6 has a large-area contact region 6a above the trench isolation region 4. A contact 27 extending from the upper interconnect is connected to the contact region 6a.

Furthermore, for CMOS devices with a dual-gate structure, impurity implantation is carried out using the following reticle layers (hereinafter, simply referred to as “layers”) for generating an implantation mask.

FIGS. 4A and 4B are diagrams showing parts of potential reference layers used in an impurity implantation process step of a CMOS device fabrication process and types of layers for ion implantation into a polysilicon film for the formation of a gate of an NMISFET (hereinafter, referred to as “NMIS gate implantation layers”). In FIGS. 4A and 4B, hatched regions show regions into which impurity ions are to be implanted, and blank regions correspond to openings of implantation masks. As shown in FIG. 4A, there are prepared, as potential reference layers, a layer for ion implantation into a substrate for the formation of an N-type well of a PMISFET (hereinafter, referred to as “N-type well implantation layer), a layer for ion implantation into the substrate for the formation of a P-type well of the NMISFET (hereinafter, referred to as “P-type well implantation layer”), a layer for ion implantation into the substrate for the formation of a P-type well of the PMISFET (hereinafter, referred to as “P-type well implantation layer”), a layer for ion implantation into the substrate for the formation of source/drain regions of the NMISFET (hereinafter, referred to as “NMIS-SD implantation laye” that is an abbreviation for an NMISFET source/drain implantation layer), and a layer for ion implantation into the substrate for the formation of source/drain regions of the PMISFET (hereinafter, referred to as “PMIS-SD implantation layer” that is an abbreviation for a PMISFET source/drain implantation layer). In principal, these potential reference layers are utilized to generate an implantation layer in implanting impurity ions into regions other than wells and source/drain regions. In this relation, there can exist layers for ion implantation into special regions in addition to the layers shown in FIG. 4A.

In this case, the NMIS gate implantation layer is generally automatically generated from the potential reference layers shown in FIG. 4A. As shown in FIG. 4B, known methods for generating an NMIS gate implantation layer include:
(a) a method in which the NMIS gate implantation layer is automatically generated from a well implantation layer;
(b) a method in which the NMIS gate implantation layer is automatically generated from an NMIS-SD implantation layer; and
(c) a method in which the NMIS gate implantation layer is automatically generated from a PMIS-SD implantation layer.

If there exist only source/drain regions of an NMISFET as a semiconductor region containing impurities at a high concentration in a P-type well and there exist only source/drain regions of a PMISFET as a semiconductor region containing impurities at a high concentration in an N-type well, an impurity implantation process step is relatively simple. However, as shown in FIG. 2A, the P-type well 2 includes the well contact region 22 into which an N-type impurity is implanted at a high concentration, and the N-type well 3 includes the well contact region 24 into which a P-type impurity is implanted at a high concentration. Hence, the conditions of an impurity implanted into a polysilicon film significantly vary depending on which of the layers formed by the methods shown in FIG. 4B is selected.

FIGS. 5A through 5C are diagrams showing the structures of respective NMIS gate implantation layers formed by the known methods (a) through (c) and respective gate polysilicon films under the use of the methods (a) through (c) in this order. Under the use of the method (a), the same mask data as those on a P-type well implantation layer are created or mask data are created by the inversion of an N-type well implantation layer. Under the use of the method (b), the same mask data as those on the NMIS-SD implantation layer are used. Under the use of the method (c), mask data are created by the inversion of the PMIS-SD implantation layer.

As shown in FIG. 5A, under the use of the known method (a), five PN junctions (▴ in the figures) and four non-doped regions (outline arrows in the figures) exist in the gate polysilicon film. As shown in FIG. 5B, under the use of the known method (b), nine PN junctions and eight non-doped regions exist in the gate polysilicon film. As shown in FIG. 5C, under the use of the known method (c), ten PN junctions exist in the gate polysilicon film but no non-doped region exists therein.

As described above, how PN junctions and non-doped regions exist in the gate polysilicon film significantly varies depending on which method is used to create the NMIS gate implantation layer.

By the way, it is known that a silicide film located on a gate polysilicon film is inevitably physically broken at a certain probability due to the existence of particles or agglomeration of silicide. Many suggestions about a process for suppressing the break of the suicide film have been made even until now. However, now that the sizes of chips are further increased and gate lengths are reduced to 0.1 μm or less, it is becoming technically more difficult to completely eliminate the break of the silicide film. When the silicide film is broken at PN junctions and lightly-doped regions (non-doped regions) in the gate polysilicon film, this leads to electrical connection failures, for example, the occurrence of regions of electrically extremely high resistance.

As shown in FIG. 5B, when the known NMIS gate implantation layer is used, there exist many PN junctions and non-doped regions in the gate polysilicon film. Therefore, it is difficult to reduce the probability of killer defects.

### SUMMARY OF THE INVENTION

An object of the present invention is to reduce electrical connection failures by reducing the number of non-doped regions and PN junctions in a gate polysilicon film in a CMOS device having a dual-gate structure.

A CMOS device of the present invention comprises a gate polysilicon film including an N-type region partly serving as a gate electrode of an NMISFET, wherein the N-type region contains an N-type impurity that is ion-implanted into a region obtained by combining a P-type well with a region of an N-type well other than part thereof into which ions are implanted to form the source/drain regions for the PMISFET and NMISFET.

In this way, non-doped regions can be eliminated while the number of PN junctions in the gate polysilicon film is reduced. This can restrain electrical connection failures from occurring due to the break of a silicide film on a non-doped region.

A method for fabricating a CMOS device of the present invention comprises the steps of, before the patterning of a polysilicon film for a gate, implanting N-type impurity ions into the polysilicon film for the gate by using an implantation mask in which a region obtained by combining the P-type well with a region of the N-type well other than part thereof into which ions are implanted to form the source/drain regions for the PMISFET and NMISFET is opened and then forming a gate polysilicon film. . With this method, non-doped regions can be eliminated while the number of PN junctions in the gate polysilicon film is reduced. This can restrain electrical connection failures from occurring due to the break of a silicide film on a non-doped region.

A method for generating mask data on an implantation mask of the present invention comprises the step of generating mask data on an implantation mask for the implantation of an N-type impurity into a polysilicon film before the patterning of the polysilicon film into the gate polysilicon film by adding (a) mask data on an implantation mask for ion implantation into a substrate for the formation of a P-type well and (b) data obtained by removing mask data on implantation masks for ion implantation into the substrate for the formation of source/drain regions for the PMISFET and NMISFET from mask data on an ion implantation mask for ion implantation into the substrate for the formation of an N-type well.

If an implantation mask is formed using the mask data generated by this method, non-doped regions can be eliminated while the number of PN junctions in the gate polysilicon film is reduced. This can restrain electrical connection failures from occurring due to the break of a silicide film on a non-doped region.

As described above, according to the CMOS device, a method for fabricating the same and a method for generating mask data of the present invention, non-doped regions can be eliminated while the number of PN junctions in the gate polysilicon film is reduced. This can restrain electrical connection failures from occurring due to the break of a silicide film on a non-doped region.

### BRIEF DESCRIPTION OF THE DRAWINGS

FIG. 1 is a diagram showing reference layers and an NMIS gate implantation layer both used in an impurity implantation process step of a CMOS device fabricating process of an embodiment and PN junctions and non-doped regions both existing in a gate polysilicon film.

FIGS. 2A and 2B are a plan view showing the structure of a typical CMOS inverter circuit and a cross-sectional view taken along the line II-II of FIG. 2A, respectively.

FIG. 3 is a diagram showing the structure of each of implantation masks and a gate polysilicon film when impurities are implanted into the gate polysilicon film having the layout shown in FIGS. 2A and 2B by using the implantation layer shown in FIG. 1.

FIGS. 4A and 4B are diagrams showing parts of potential reference layers used in the impurity implantation process step of a CMOS device fabricating process and types of NMIS gate implantation layers.

FIGS. 5A through 5C are diagrams showing the structures of respective NMIS gate implantation layers formed by the known methods (a) through (c) and respective gate polysilicon films under the use of the methods (a) through (c) in this order.

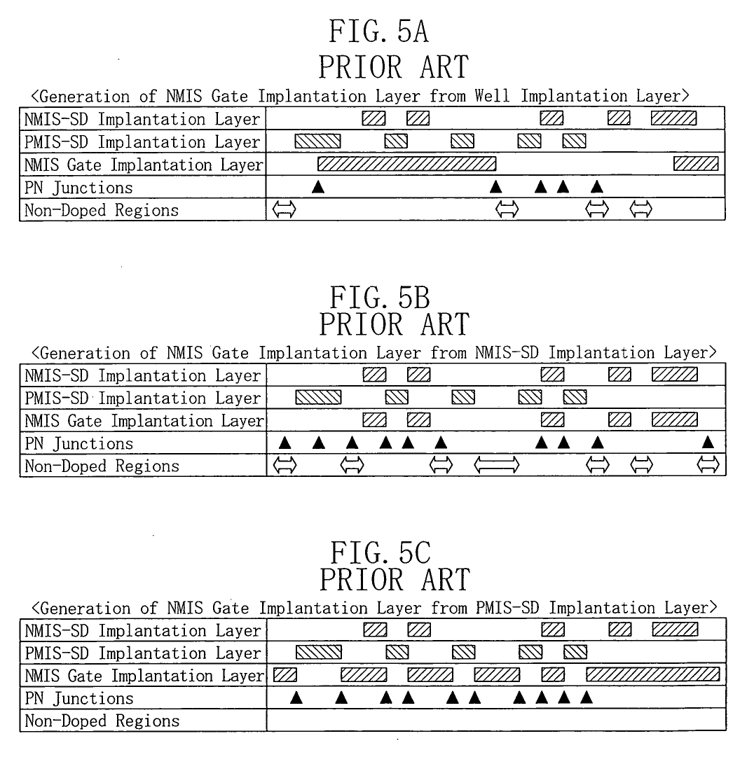

### DETAILED DESCRIPTION OF THE INVENTION

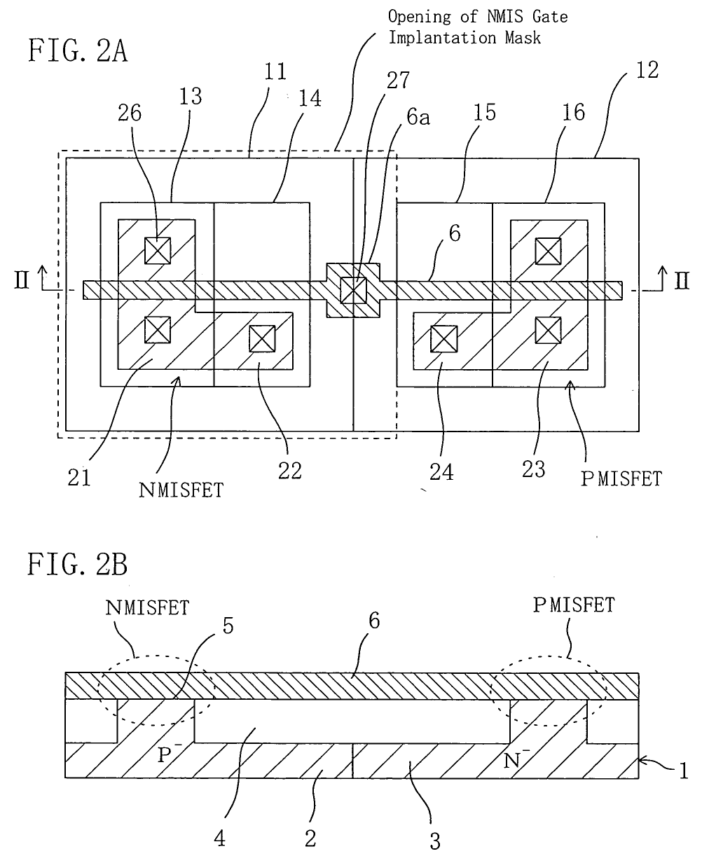

An embodiment of the present invention is predicated on a CMOS device having a part constituting an inverter circuit as shown in FIGS. 2A and 2B.

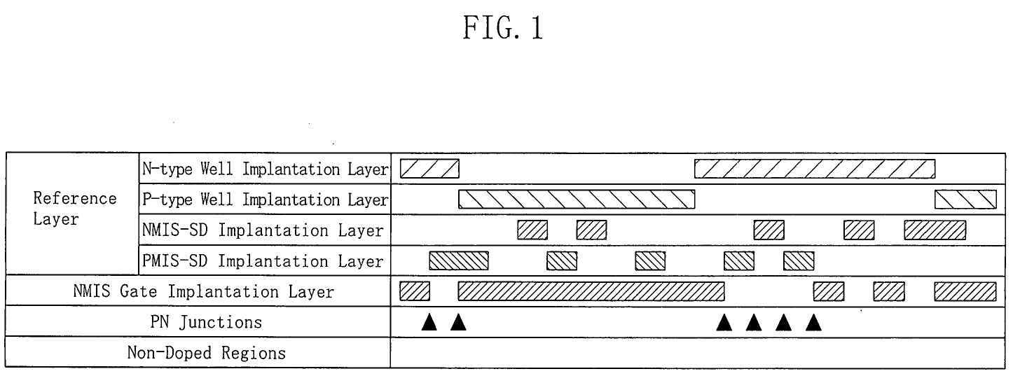

FIG. 1 is a diagram showing reference layers and an NMIS gate implantation layer both used in an impurity implantation process step of a CMOS device fabricating process of an embodiment and PN junctions and non-doped regions both existing in a gate polysilicon film.

As shown in FIG. 1, the NMIS gate implantation layer is generated by the method in which the mask data of a P-type well implantation layer are added to mask data obtained by subtracting the mask data of an NMIS-SD implantation layer and PMIS-SD implantation layer from the mask data of an N-type well implantation layer.

As a result, as shown in FIG. 1, although six PN junctions exist in the gate polysilicon film of the CMOS device of this embodiment, no non-doped region exists therein. Therefore, as compared with the use of respective NMIS gate implantation layers generated by the known methods (a) through (c), what results is as follows. Although the use of the NMIS gate implantation layer generated by the method of this embodiment increases the number of PN junctions by one as compared with the method (a), it does not provide any non-doped region. Furthermore, it drastically reduces both the numbers of PN junctions and non-doped regions as compared with the use of the NMIS gate implantation layer generated by the known method (b). In addition, it reduces the number of PN junctions from ten to six as compared with the use of the NMIS gate implantation layer generated by the known method (c).

The total numbers of PN junctions and non-doped regions are reduced as compared with either known method. More particularly, non-doped regions can be eliminated while the number of PN junctions is reduced. This can restrain electrical connection failures from occurring due to the break of a silicide film on a non-doped region even if the upper part of the gate polysilicon film is prevented from being silicided at a certain probability later.

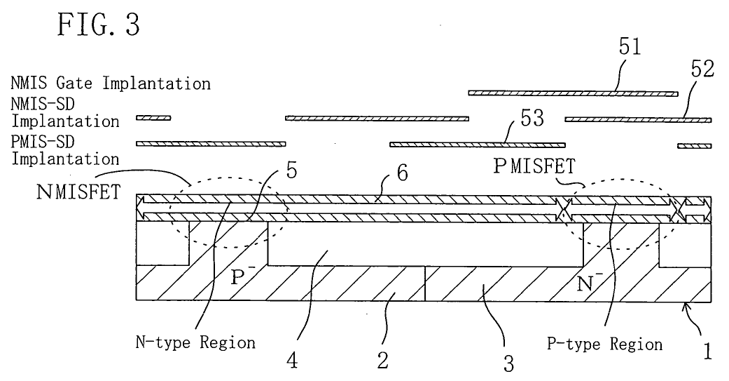

FIG. 3 is a diagram showing the structures of implantation masks and a gate polysilicon film 6 when impurities are implanted into the gate polysilicon film 6 having the layout shown in FIGS. 2A and 2B by using the implantation layers shown in FIG. 1. Before the deposition of a polysilicon film for a gate, ions are implanted into a substrate to form a P-type well 2 and an N-type well 3. Therefore, each implantation mask for implanting ions into the substrate to form each well is not shown in FIG. 3.

In a CMOS device fabricating process of this embodiment, impurity ions are implanted into the polysilicon film or the substrate using each implantation mask shown in FIG. 3 in top-to-bottom order. First, a trench is formed in a silicon substrate 1, and thereafter a trench isolation region 4 is formed by filling the trench with a silicon oxide film. Next, a gate insulating film 5 is formed on active regions surrounded by the trench isolation, and thereafter a polysilicon film for a gate is deposited on the gate insulating film 5 and the trench isolation region 4. Then, N-type impurity ions (for example, phosphorus ions) are implanted, using an implantation mask 51 formed from a MIS gate implantation layer (MIS gate implantation), into a flat-shaped polysilicon film for a gate before the patterning of the polysilicon film for the formation of the gate polysilicon film 6. Next, N-type impurity ions (for example, arsenic ions) are implanted, using an implantation mask 52 formed from an NMIS-SD implantation layer, into source/drain regions 21 of an NMISFET and a well contact region 24 of a PMISFET. Subsequently, P-type impurity ions (for example, boron ions) are implanted, using an implantation mask 53 formed from a PMIS-SD implantation layer, into source/drain regions 23 of the PMISFET and a well contact region 22 of the NMISFET. The polysilicon film for the gate is very heavily doped during ion implantation into the polysilicon film for the gate of the NMISFET. Therefore, even if the N-type region of the gate polysilicon film 6 is doped with P-type impurities during PMIS-SD implantation, the conductivity type of this region is not inverted and does not become intrinsic.

As a result, as shown in FIG. 3, the N-type region and a P-type region exist in the gate polysilicon film 6 but no non-doped region exists therein.

For example, if as shown in a broken line of FIG. 2A an opening of an NMIS gate implantation mask expands to reach a region adjacent to the opening 15 of the PMIS-SD implantation mask, this causes that the non-doped region of the gate polysilicon film 6 that has existed between the opening 14 and the opening 15 is replaced with an N-type region.

Thereafter, a metal film such as a cobalt film is deposited on the substrate, and then a known salicide process step is carried out in which a low-resistance silicide film is formed by a reaction between this metal film and each of the gate polysilicon film and the silicon substrate (source/drain regions). At this time, the upper part of the gate polysilicon film is silicided.

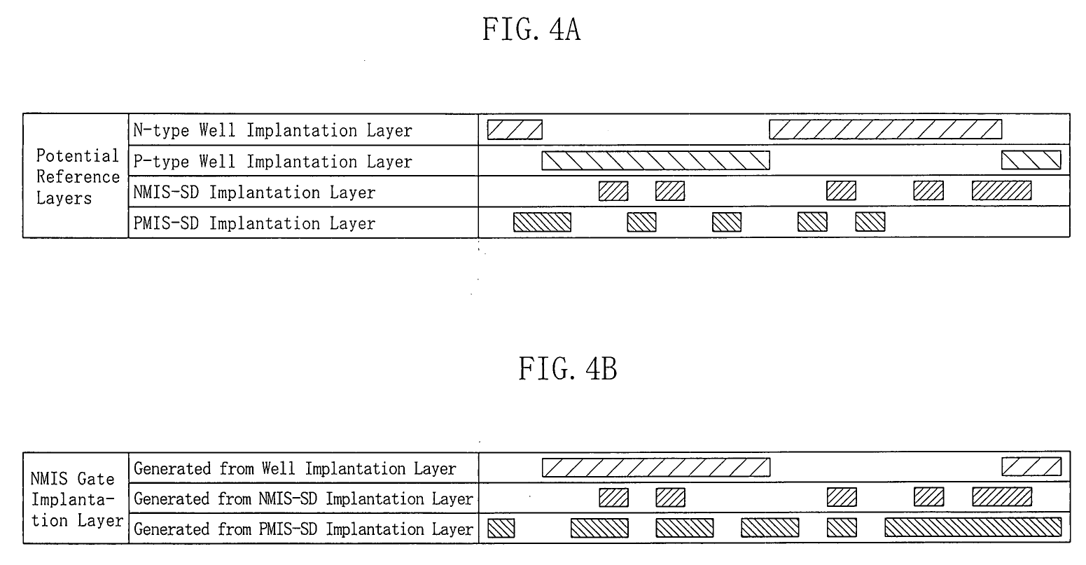

The reference layers of the NMIS gate implantation layer of this embodiment shown in FIG. 1 is the same as the potential reference layers shown in FIG. 4A. More particularly, the mask data of the NMIS gate implantation layer used in the CMOS device fabricating process of this embodiment are obtained by adding the mask data of the P-type well implantation layer to mask data obtained by subtracting the mask data of the NMIS-SD implantation layer and PMIS-SD implantation layer from the mask data of the N-type well implantation layer.

In this way, a mask data generation process step is carried out in which the mask data of the N-type well implantation layer is created by removing the mask data of the NMIS-SD implantation layer and PMIS-SD implantation layer from the mask data of the N-type well implantation layer. As a result, the total numbers of PN junctions and non-doped regions in the gate polysilicon film can be reduced as compared with the known mask data generation methods shown in FIG. 4B. In particular, non-doped regions can be eliminated.

The present invention can be widely utilized for CMOS devices built into various types of electronic equipment and the fabrication of the CMOS devices.

1. A CMOS device having an NMISFET and a PMISFET, said CMOS device comprising:
a P-type well;
source/drain regions for the NMISFET formed in the upper part of the P-type well;
an N-type well;
source/drain regions for the PMISFET formed in the upper part of the N-type well; and
a gate polysilicon film including an N-type region and a P-type region, said N-type region partly serving as a gate electrode of the NMISFET and said P-type region partly serving as a gate electrode of the PMISFET,
wherein the N-type region of the gate polysilicon film contains an N-type impurity that is ion-implanted, before the patterning of a polysilicon film into the gate polysilicon film, into a region obtained by combining the P-type well with a region of the N-type well other than part thereof into which ions are implanted to form the source/drain regions for the PMISFET and NMISFET.

2. A method for fabricating a CMOS device having an NMISFET and a PMISFET, said method comprising the steps of:
(a) depositing a polysilicon film for a gate on a semiconductor substrate formed with a P-type well and an N-type well;
(b) implanting N-type impurity ions into the polysilicon film for the gate by using an implantation mask in which a region obtained by combining the P-type well with a region of the N-type well other than part thereof into which ions are implanted to form the source/drain regions for the PMISFET and NMISFET is opened;
(c) patterning the polysilicon film for the gate to form a gate polysilicon film partly serving as a gate electrode of the NMISFET and partly serving as a gate electrode of the PMISFET after the step (b);
(d) forming source/drain regions for the NMISFET in the upper part of the P-type well; and
(e) forming source/drain regions for the PMISFET in the upper part of the N-type well.

3. A method for generating mask data on an implantation mask used in a fabrication process for a CMOS device comprising a gate polysilicon film having an N-type region partly serving as a gate electrode of an NMISFET and a P-type region partly serving as a gate electrode of a PMISFET, said method comprising the step of
generating mask data on an implantation mask for the implantation of an N-type impurity into a polysilicon film before the patterning of the polysilicon film into the gate polysilicon film by adding (a) mask data on an implantation mask for ion implantation into a substrate for the formation of a P-type well and (b) data obtained by removing mask data on implantation masks for ion implantation into the substrate for the formation of source/drain regions for the PMISFET and NMISFET from mask data on an ion implantation mask for ion implantation into the substrate for the formation of an N-type well.
